(19) United States
(12) Patent Application Publication
(10) Pub. No.: US 2003/0090937 A1
(43) Pub. Date: May 15, 2003

(54) DRAM-based flash memory unit

(76) Inventor: Han-ping Chen, Saratoga, CA (US)

Correspondence Address: Han-ping Chen, P.O. Box 2871, Saratoga, CA, 95070, US

(21) Appl. No.: 09/987,214

(22) Filed: Nov. 14, 2001

(51) Int. Cl. G11C 11/34

(52) U.S. Cl. 365/185.08

(57) ABSTRACT

A method and apparatus performs memory read and write operations according to a standard flash memory interface using more cost-effective DRAM devices while maintaining the non-volatile characteristics of a flash memory device using a standby power source. Also, the present invention provides a method that replaces defective memory cell locations with functional memory cell locations.

### BACKGROUND OF THE INVENTION

This invention relates to flash memory devices, dynamic random-access memory (DRAM) devices, and memory modules.

Flash memory devices are non-volatile as they retain the memory contents in the absence of a power supply. As such, they are often used in add-on cards or modules for portable electronic systems such as digital cameras, audio players, personal digital assistants (PDA), and notebook computers.

However, due to the process complexity, the cost of a flash memory device is significantly higher than a dynamic random-access memory (DRAM) device of the same storage capacity.

In fact, the cost of a small number of flash memory add-on cards may exceed the cost of the portable electronic system itself.

This cost factor limits the number of add-on cards one may afford to have in association with a portable electronic system. This factor also limits the market popularity and the installation base for the particular portable electronic system.

Users are constantly seeking for a low-cost solution to the portability, flexibility, extendibility, and affordability of a portable system.

### BRIEF SUMMARY OF THE INVENTION

This invention proposes a method and apparatus to build flash memory units with low-cost dynamic random-access memory devices.

This invention provides a method that maintains the same flash memory device interface to the remaining part of the electronic subsystem or system.

The present invention provides a method to directly replace existing flash memory devices with DRAM-based devices in existing portable electronic systems or add-on modules.

The present invention further provides a method that can be implemented with the least efforts and in the least amount of time.

### BRIEF DESCRIPTION OF THE DRAWINGS

FIG. 1 is a diagram of a prior art flash memory add-on module.

FIG. 2 shows a preferred embodiment of the present invention for a DRAM-based flash memory add-on module.

FIG. 3 shows another preferred embodiment of the present invention for a DRAM-based flash memory add-on module.

FIG. 4 shows a preferred embodiment of the present invention for a DRAM-based flash memory controller unit.

### DETAILED DESCRIPTION OF THE INVENTION

The present invention will be illustrated with some preferred embodiments.

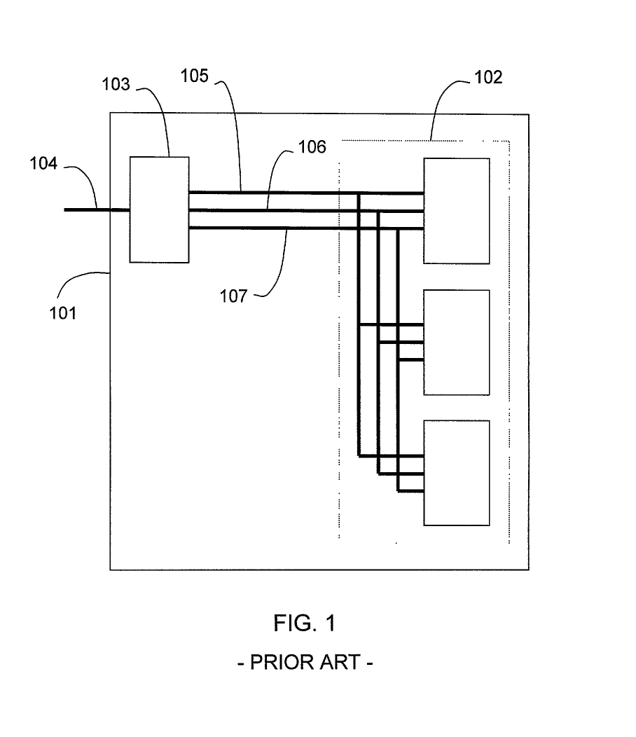

FIG. 1 is a diagram of a prior art flash memory add-on module. The flash memory add-on module 101 contains one or more flash memory devices 102 and an optional flash memory module controller unit 103.

The flash memory add-on module 101 interfaces with the external system through the memory module interface 104. The memory module interface 104 contains explicit or implicit memory address, memory control, and memory data signals. These signals may be space-multiplexed, time-multiplexed, or formatted according to certain protocol specification.

The optional flash memory module controller unit 103 transforms the memory module signals from the memory module interface 104 into flash memory signals on the flash memory address lines 105, flash memory control lines 106, and flash memory data lines 107.

The optional flash memory module controller unit 103 also receives flash memory signals from the flash memory data lines 107 and transforms the flash memory signals into memory module signals on the memory module interface 104.

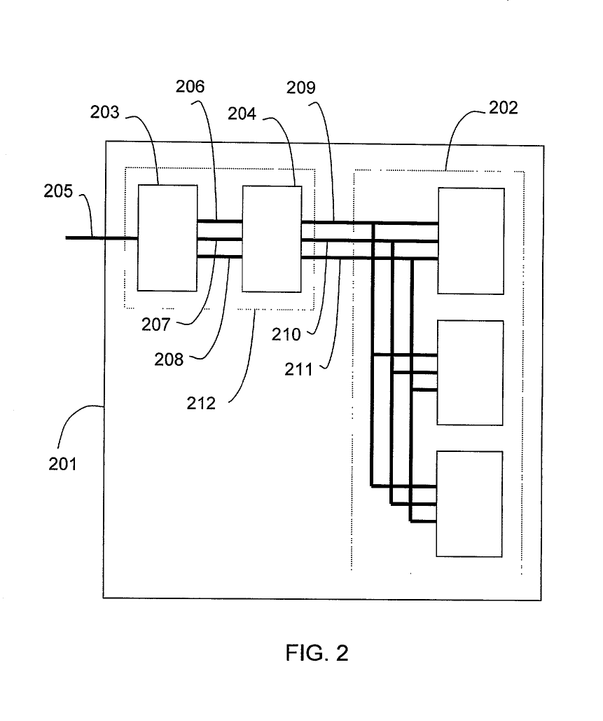

FIG. 2 shows a preferred embodiment of the present invention for a DRAM-based flash memory add-on module. The DRAM-based flash memory add-on module 201 consists of one or more DRAM devices 202, an optional flash memory module controller unit 203, and a DRAM-based flash memory controller unit 204.

The flash memory add-on module 201 interfaces with the external system through the memory module interface 205. The memory module interface 205 contains explicit or implicit memory address, memory control, and memory data signals. These signals may be space-multiplexed, time-multiplexed, or formatted according to certain protocol specification.

The optional flash memory module controller unit 203 transforms the memory module signals from the memory module interface 205 into flash memory signals on the flash memory address lines 206, flash memory control lines 207, and flash memory data lines 208.

The optional flash memory module controller unit 203 also receives flash memory signals from the flash memory data lines 208 and transforms the flash memory signals into memory module signals on the memory module interface 205.

The DRAM-based flash memory controller 204 receives flash memory signals on the flash memory address lines 206, flash memory control lines 207, and flash memory data lines 208. The controller transforms these flash memory signals into DRAM signals on the DRAM address lines 209, DRAM control lines 210, and DRAM data lines 211.

The DRAM-based flash memory controller 204 receives DRAM signals from the DRAM data lines 211 and transforms the DRAM signals into flash memory signals on the flash memory data lines 208.

For certain applications, a DRAM-based flash memory controller 204 may be integrated with a flash memory module controller unit 203 to form a DRAM-based flash memory module controller unit 212.

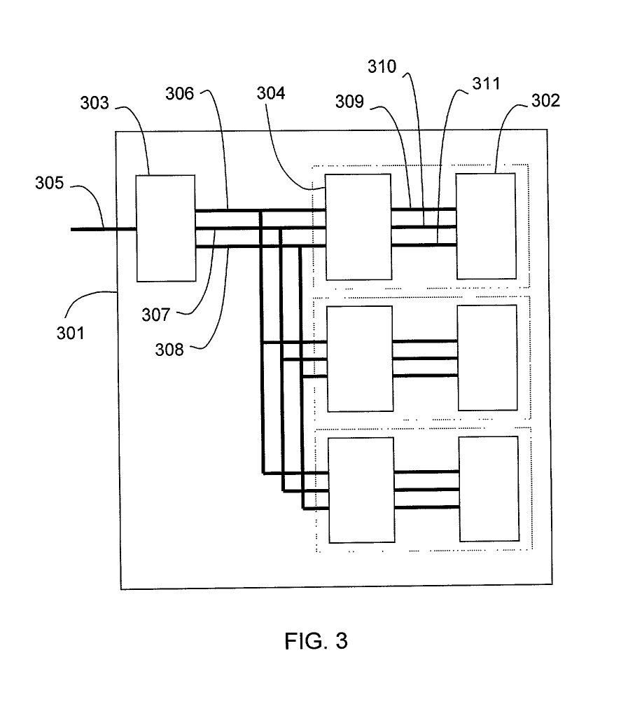

FIG. 3 shows another preferred embodiment of the present invention for a DRAM-based flash memory add-on module. In this preferred embodiment, there is a dedicated DRAM-based flash memory controller for each DRAM device.

The DRAM-based flash memory add-on module 301 consists of one or more DRAM devices 302, an optional flash memory module controller unit 303, and one or more DRAM-based flash memory controller units 304.

The flash memory add-on module 301 interfaces with the external system through the memory module interface 305. The memory module interface 305 contains explicit or implicit memory address, memory control, and memory data signals. These signals may be space-multiplexed, time-multiplexed, or formatted according to certain protocol specification.

The optional flash memory module controller unit 303 transforms the memory module signals from the memory module interface 305 into flash memory signals on the flash memory address lines 306, flash memory control lines 307, and flash memory data lines 308.

The optional flash memory module controller unit 303 also receives flash memory signals from the flash memory data lines 308 and transforms the flash memory signals into memory module signals on the memory module interface 305.

The DRAM-based flash memory controller 304 receives flash memory signals on the flash memory address lines 306, flash memory control lines 307, and flash memory data lines 308. The controller transforms these flash memory signals into DRAM signals on the DRAM address lines 309, DRAM control lines 310, and DRAM data lines 311.

The DRAM-based flash memory controller 304 receives DRAM signals from the DRAM data lines 311 and transforms the DRAM signals into flash memory signals on the flash memory data lines 308.

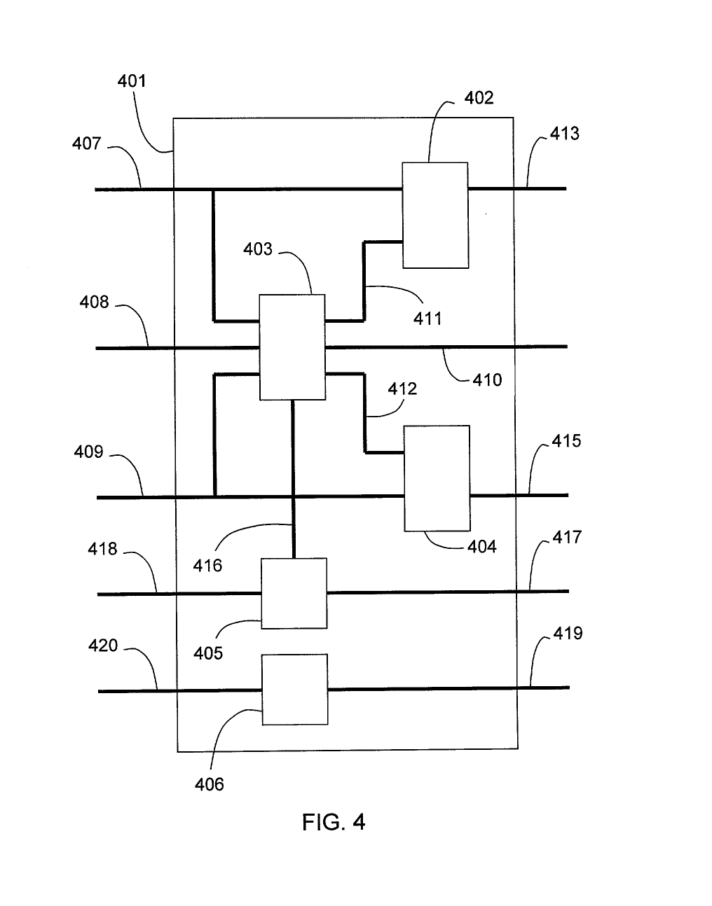

FIG. 4 shows a preferred embodiment of the present invention for a DRAM-based flash memory controller unit.

The DRAM-based flash memory controller unit 401 consists of a memory address interface unit 402, a memory control unit 403, an optional memory data interface unit 404, an optional clock-timing unit 405, and an optional power supply unit 406.

The memory control unit 403 receives flash memory signals from the flash memory control lines 408. it may also receive flash memory signals from flash memory address lines 407 and flash memory data lines 409. The memory control unit generates DRAM control signals on the DRAM control lines 410.

The memory control unit also generates DRAM address control signals on the DRAM address control lines 411. It may also generate DRAM data control signals on the DRAM data control lines 412.

When attached to an external system, the memory control unit 403 transforms flash memory read and write access control signals into DRAM read and write access control signals. It also generates DRAM refresh control signals at the appropriate time.

When detached from an external system, the DRAM-based flash memory controller unit 401 operates in a standby mode. The memory control unit 403 only generates memory refresh control signals to the DRAM devices to maintain the DRAM memory contents.

The memory address interface unit 402 receives flash memory address signals from the flash memory address lines 407 and DRAM address control signals from DRAM address control lines 411.

For memory read and write operations, the memory address interface unit 402 multiplexes the flash memory address into DRAM row and column address signals on the DRAM address lines 413.

Upon control signals from the memory control unit 403, the memory address interface unit 402 may also generate signals on the DRAM memory address lines to control the DRAM operational modes.

The optional memory data interface unit 402 receives DRAM data control signals from DRAM data control lines 412. The memory data interface unit 404 controls the memory data input and output between the flash memory data lines 409 and DRAM data lines 415.

The optional clock-timing unit 405 generates clock-timing signals 416 to the memory control unit 403. The clock-timing unit 405 also sends DRAM clock-timing signals 417 to the DRAM devices.

When attached to an external system, the clock-timing unit 405 may receive external clock-timing signals 418 to use as a timing base.

The optional power supply unit 406 generates power for the logic units in the flash memory controller unit 401. The power supply unit 406 also sends power 419 to the DRAM devices.

When attached to an external system, the power supply unit 406 may receive external power 420 from the external system in order to preserve power for standby use only.

The memory control unit 403 may also contain control logic to detect certain memory address locations that contain defective memory cells. The control unit may send signals to the memory address interface unit 402 to re-map the memory address to specified DRAM address locations that contain functional memory cells.

The address re-mapping information may be hard-wired in the control logic or stored in internal or external memory cells.

I claim:

1. A DRAM-based flash memory controller unit comprising:
(a) a plurality of flash memory address lines;
(b) a plurality of flash memory control lines;
(c) a plurality of DRAM address lines;
(d) a plurality of DRAM control lines;
(e) a memory access control unit;
(f) a clock-timing unit;
(g) a standby power unit;
wherein said memory access control unit generates DRAM control signals on said DRAM control lines, at least in part, according to the flash memory control signals on said flash memory control lines;
wherein the DRAM address signals on said DRAM address lines are generated, at least in part, according to the flash memory address signals on said flash memory address lines and control signals from said memory access control unit;
wherein said memory access control unit generates DRAM control signals on said DRAM control lines to maintain the memory contents, at least in the absence of external power supply;
wherein said clock-timing unit provides a plurality of clock-timing signals to said memory access control unit, at least in the absence of external clock-timing signals;
wherein said standby power unit provides power to said DRAM-based flash memory controller unit, at least in the absence of external power supply.

2. The DRAM-based flash memory controller unit of claim 1 wherein said standby power unit is a plurality of batteries or capacitors.

3. The DRAM-based flash memory controller unit of claim 1 further comprises a plurality of DRAM devices to form a DRAM-based flash memory unit with standard flash memory interface.

4. The DRAM-based flash memory controller unit of claim 1 further comprises a flash memory module controller unit to form a DRAM-based flash memory module controller unit with a specific module interface protocol.

5. The DRAM-based flash memory controller unit of claim 1 further comprises memory address re-mapping logic to re-map memory address locations with defective memory cells to memory address locations with functional memory cells.

6. The DRAM-based flash memory controller unit of claim 1 further comprises a plurality of flash memory data lines and a plurality of DRAM data lines wherein said memory access control unit controls the memory data input and output between said flash memory data lines and said DRAM data lines.

7. A DRAM-based flash memory controller unit comprising:
(a) a plurality of flash memory address lines;
(b) a plurality of flash memory control lines;
(c) a plurality of DRAM address lines;
(d) a plurality of DRAM control lines;
(e) a memory access control unit;
wherein said memory access control unit generates DRAM control signals on said DRAM control lines, at least in part, according to the flash memory control signals on said flash memory control lines;
wherein the DRAM address signals on said DRAM address lines are generated, at least in part, according to the flash memory address signals on said flash memory address lines and control signals from said memory access control unit.

8. The DRAM-based flash memory controller unit of claim 7 further comprises a plurality of DRAM devices to form a DRAM-based flash memory unit with standard flash memory interface.

9. The DRAM-based flash memory controller unit of claim 7 further comprises a flash memory module controller unit to form a DRAM-based flash memory module controller unit with a specific module interface protocol.

10. The DRAM-based flash memory controller unit of claim 7 further comprises memory address re-mapping logic to re-map memory address locations with defective memory cells to memory address locations with functional memory cells.

11. The DRAM-based flash memory controller unit of claim 7 further comprises a plurality of flash memory data lines and a plurality of DRAM data lines wherein said memory access control unit controls the memory data input and output between said flash memory data lines and said DRAM data lines.

12. A DRAM-based non-volatile memory controller unit comprising:
(a) a plurality of memory module interface lines;
(b) a plurality of DRAM address lines;
(c) a plurality of DRAM control lines;
(d) a memory access control unit;
(e) a clock-timing unit;
(f) a standby power unit;
wherein said memory access control unit generates DRAM control signals on said DRAM control lines, at least in part, according to the interface signals on said memory module interface lines;
wherein the DRAM address signals on said DRAM address lines are generated, at least in part, according to the interface signals on said memory module interface lines and control signals from said memory access control unit.
wherein said memory access control unit generates DRAM control signals on said DRAM control lines to maintain the memory contents, at least in the absence of external power supply;
wherein said clock-timing unit provides a plurality of clock-timing signals to said memory access control unit, at least in the absence of external clock-timing signals;
wherein said standby power unit provides power to said DRAM-based non-volatile memory controller unit, at least in the absence of external power supply.

13. The DRAM-based non-volatile memory controller unit of claim 12 wherein said standby power unit is a plurality of batteries or capacitors.

14. The DRAM-based non-volatile memory controller unit of claim 12 further comprises a plurality of DRAM devices to form a DRAM-based nonvolatile memory unit.

15. The DRAM-based non-volatile memory controller unit of claim 12 further comprises memory address re-mapping logic to re-map memory address locations with defective memory cells to memory address locations with functional memory cells.

16. The DRAM-based non-volatile memory controller unit of claim 12 further comprises a plurality of DRAM data lines wherein said memory access control unit controls the memory data input and output between said memory module interface lines and said DRAM data lines.
